(19) United States
(12) Patent Application Publication
(10) Pub. No.: US 2010/0128457 A1
(43) Pub. Date: May 27, 2010

(54) FAN UNIT MOUNTING STRUCTURE

(76) Inventor: Tomoyuki Ooya, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/595,851

(22) PCT Filed: Mar. 26, 2008
(86) PCT No.: PCT/JP2008/000726

§ 371 Date: Oct. 14, 2009

(51) Int. Cl. H02B 1/01; H05K 7/20

(52) U.S. Cl. 361/825; 361/695

(57) ABSTRACT

A plurality of fan unit mounting projections are each extended substantially in parallel with a rotary shaft of a fan included in a fan unit and are provided integrally to a fan unit mounting part. A belt-shaped elastic body is hung onto each of the fan unit mounting projections, and is made in contact with a plurality of locations on an outer peripheral part of the fan unit. The fan unit is retained, while being spaced apart from the fan unit mounting part in a direction along the rotary shaft of the fan, due to a clipping force of the belt-shaped elastic body.

### TECHNICAL FIELD

The present invention relates to a fan unit mounting structure used for mounting a fan unit to a fan unit mounting part provided in a casing of an electronic device.

### BACKGROUND ART

In an electronic device such as a liquid crystal display device or a plasma display device, there is mounted a fan unit having a fan for ventilating a casing in order to inhibit the temperature therein from being risen due to heat generated by a heat generating component that is disposed in the casing.

One of conventional structures used for mounting fan units of this type is disclosed in Patent Document 1 (Japanese Unexamined Patent Publication No. Hei. 8-172287).

As shown in FIG. 14A, a fan unit 100 according to Patent Document 1 includes a fan 101 that is provided with a plurality of rotary blades, a fan housing 102 that accommodates the fan 101 so as to be rotatable therein, and a band clevis 103 that has a substantially U-letter shape in cross section and surrounds to retain the fan housing 102.

As shown in FIG. 14B, the band clevis 103 is provided at two ends thereof with screwing holes 103a and 103a respectively so as to correspond to screw holes 104a and 104a that are formed in a fan unit mounting part 104 disposed in a casing of an electronic device. The fan unit 100 is mounted to the fan unit mounting part 104 with use of screws 105 that are fitted in the screw holes 104a and 104a in the fan unit mounting part 104 through the screwing holes 103a and 103a, respectively.

However, in such a case as described above of mounting the fan unit 100 with use of the screws 105, vibration of the fan unit 100 caused by the driven (rotating) fan 101 is transmitted to the fan unit mounting part 104 by way of the screws 105, thereby resulting in a problem of noise generation.

In order to solve this problem, there are provided in the fan unit 100 according to Patent Document 1 elastic plates 106 (see FIG. 14A) at three locations between the fan housing 102 and the band clevis 103, and there is also provided an elastic plate 107 (see FIG. 14B) between the fan housing 102 and the fan unit mounting part 104. These elastic plates 106 and 107 inhibit vibration of the fan unit 100 from being transmitted to the fan unit mounting part 104.

As in Patent Document 2 (Japanese Unexamined Patent Publication No. 2001-313483) other than Patent Document 1, there is disclosed another fan unit mounting structure suppressive of such transmission of vibration.

According to the fan unit mounting structure disclosed in Patent Document 2, in order to mount a fan unit, a fan housing has four corners each of which is fitted with an elastic body having a concave part therein, and the fan unit is inserted to a receiving part of a casing of an electronic device. In this configuration, the fan unit is made in contact with the casing (the fan unit mounting part) with the four elastic bodies each interposed therebetween. Therefore, the transmission of vibration is suppressed by the respective elastic bodies.

### DISCLOSURE OF THE INVENTION

### Problems to be Solved by the Invention

Nevertheless, each of the fan unit mounting structures described above involves a large number of components as there are required a screw and an elastic body at each of the locations (generally four) to be fixed. More specifically, the mounting structure according to Patent Document 1 requires at least a band clevis, four elastic bodies, and two screws, while the mounting structure according to Patent Document 2 requires at least four elastic bodies and a receiving part. Therefore, there are necessarily increased the number of assembling steps.

Moreover, the elastic bodies adopted in Patent Documents 1 and 2 are each required to have a smaller size relative to the fan unit as well as to be set to have a low degree of hardness (to be soft) (such as the hardness less than 40 degrees) in order to have a vibration-proofing property. Such elastic bodies are deformable even with a slight external force applied thereto, and thus the mounting operation involving such an elastic body requires increased difficulty as well as quite a lot of working hours. In addition, such an elastic body may be easily damaged or displaced, thereby highly possibly resulting in a poor quality.

In order to solve the above problems, it is therefore an object of the present invention to provide a fan unit mounting structure that realizes suppression of noise by inhibiting transmission to a fan unit mounting part of vibration caused by a driven fan, as well as facilitates an operation of mounting the fan unit.

### Means for Solving the Problems

In order to achieve the above object, the present invention provides the following configurations.

According to a first aspect of the present invention, there is provided a fan unit mounting structure used for mounting a fan unit to a fan unit mounting part in a casing of an electronic device, the structure comprising:

a plurality of fan unit mounting projections each extended substantially in parallel with a rotary shaft of a fan included in the fan unit and provided integrally to the fan unit mounting part; and

a belt-shaped elastic body hung onto each of the fan unit mounting projections,

the belt-shaped elastic body being made in contact with a plurality of locations on an outer peripheral part of the fan unit, and the fan unit being retained, while being spaced apart from the fan unit mounting part in a direction along the rotary shaft of the fan, due to a clipping force of the belt-shaped elastic body.

According to a second aspect of the present invention, there is provided the fan unit mounting structure as defined in the first aspect, wherein the fan unit mounting projections are provided to a fan unit mounting frame that is integrally fixed to the fan unit mounting part.

According to a third aspect of the present invention, there is provided the fan unit mounting structure as defined in the second aspect, wherein a plurality of contact portions between the belt-shaped elastic body and the outer peripheral part of the fan unit are located so as to be distant respectively from a plurality of contact portions between the belt-shaped elastic body and the respective fan unit mounting projections.

According to a fourth aspect of the present invention, there is provided the fan unit mounting structure as defined in the third aspect, wherein

the fan unit includes a plurality of flange parts on the outer peripheral part thereof,

the belt-shaped elastic body has a plurality of holes at positions respectively corresponding to the flange parts, and

the belt-shaped elastic body is hung onto each of the fan unit mounting projections, the flange parts of the fan unit are inserted respectively to the holes in the belt-shaped elastic body, and the fan unit is retained, while being spaced apart from the fan unit mounting part in the direction along the rotary shaft of the fan, due to the clipping force of the belt-shaped elastic body.

According to a fifth aspect of the present invention, there is provided the fan unit mounting structure described in the third aspect, in which the belt-shaped elastic body has a degree of hardness (in accordance with JIS K6301A) ranging from 40 to 50 degrees.

According to a six aspect of the present invention, there is provided the fan unit mounting structure as defined in the third aspect, wherein the belt-shaped elastic body is made of one of a silicon rubber and a chloroprene rubber.

According to a seventh aspect of the present invention, there is provided the fan unit mounting structure as defined in the third aspect, wherein

two ends of the belt-shaped elastic body are fixedly coupled with each other so as to form a ring-shaped elastic body, and

the ring-shaped elastic body is hung onto each of the fan unit mounting projections, the ring-shaped elastic body is made in contact with a plurality of locations on the outer peripheral part of the fan unit, and the fan unit is retained, while being spaced apart from the fan unit mounting part in the direction along the rotary shaft of the fan, due to the clipping force of the ring-shaped elastic body.

According to an eighth aspect of the present invention, there is provided the fan unit mounting structure as defined in the seventh aspect, wherein the ring-shaped elastic body is provided to extend from a portion for retaining the fan unit toward a discharge opening provided in the casing so as to form a discharge wind tunnel part.

According to a ninth aspect of the present invention, there is provided the fan unit mounting structure as defined in the seventh aspect, wherein the ring-shaped elastic body is provided to extend from a portion for retaining the fan unit toward a heat generating component disposed in the casing so as to form a suction wind tunnel part.

According to a tenth aspect of the present invention, there is provided the fan unit mounting structure as defined in the eighth aspect, wherein the ring-shaped elastic body has a portion for forming the wind tunnel part, a thickness of the portion being smaller than that of a portion for retaining the fan unit.

According to an 11th aspect of the present invention, there is provided the fan unit mounting structure as defined in the seventh aspect, wherein

the fan unit has a blast opening partially on the outer peripheral part, and

the ring-shaped elastic body is disposed to inclusively surround the fan unit and a heat generating component so that an airflow is guided from the blast opening toward the heat generating component disposed in the casing.

### EFFECTS OF THE INVENTION

According to the first aspect of the present invention, the belt-shaped elastic body is hung onto the plurality of fan unit mounting projections that are provided integrally to the fan unit mounting part (such as the casing or the device body disposed in the casing). Further, according to the first aspect of the present invention, the belt-shaped elastic body is made in contact with the plurality of locations on the outer peripheral part of the fan unit, so that the fan unit is retained, while being spaced apart from the fan unit mounting part in the direction along the rotary shaft of the fan, due to the clipping force of the belt-shaped elastic body.

In other words, the fan unit is clipped by the belt-shaped elastic body so as to be retained while being floated from the fan unit mounting part in the direction along the rotary shaft of the fan. Accordingly, even in a case where vibration is generated by the driven fan, such vibration is absorbed by the belt-shaped elastic body, thereby suppressing transmission of the vibration to the fan unit mounting part.

More specifically, vibration caused in a direction perpendicular to the rotary shaft of the fan is absorbed by the belt-shaped elastic body that is bent in the perpendicular direction while clipping the fan unit. It is therefore possible to suppress transmission of the vibration in the direction perpendicular to the rotary shaft of the fan to the fan unit mounting projections provided integrally to the fan unit mounting part.

On the other hand, vibration caused in a direction along the rotary shaft of the fan is absorbed by the belt-shaped elastic body that is bent in the direction along the rotary shaft while clipping the fan unit. It is therefore possible to suppress transmission of the vibration in the direction along the rotary shaft of the fan to the fan unit mounting projections provided integrally to the fan unit mounting part. In this case, the fan unit is retained while being floated from the fan unit mounting part in the direction along the rotary shaft of the fan. Therefore, it is possible to inhibit contact between the fan unit and the fan unit mounting part even in a case where the fan unit is shifted in the direction along the rotary shaft of the fan due to the bent belt-shaped elastic body. As a result, it is possible to suppress transmission to the fan unit mounting part of the vibration caused by the driven fan so as to achieve suppression of noise.

In comparison to any of the elastic bodies adopted in Patent Documents 1 and 2, the belt-shaped elastic body is a component obviously larger in size, thereby being hard to be deformed by a slight external force and being easily handled. Therefore facilitated is the mounting operation involving the elastic body, and the fan unit mounting operation can be easily performed.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1A is a plan view showing a state of a fan unit mounting frame and a belt-shaped elastic body respectively attached to a fan unit according to a first embodiment of the present invention;

FIG. 1B is a side view showing the state of the fan unit mounting frame and the belt-shaped elastic body respectively attached to the fan unit according to the first embodiment of the present invention;

FIG. 2A is a plan view of the fan unit according to the first embodiment of the present invention;

FIG. 2B is a side view of the fan unit according to the first embodiment of the present invention;

FIG. 3A is a plan view of the fan unit mounting frame according to the first embodiment of the present invention;

FIG. 3B is a side view of the fan unit mounting frame according to the first embodiment of the present invention;

FIG. 4 is a plan view of the belt-shaped elastic body according to the first embodiment of the present invention;

FIG. 5 is a graph indicating a relation between degrees of hardness of the belt-shaped elastic body and values of noise caused by a driven fan;

FIG. 6 is a side view showing a fan unit mounting structure according to a second embodiment of the present invention;

FIG. 7 is a side cross sectional view showing a fan unit mounting structure according to a third embodiment of the present invention;

FIG. 8 is a partially-enlarged cross sectional view of a belt-shaped elastic body according to the third embodiment of the present invention;

FIG. 9 is a side cross sectional view showing a fan unit mounting structure according to a fourth embodiment of the present invention;

FIG. 10 is a perspective view of a belt-shaped elastic body according to a modified example;

FIG. 11A is a plan view showing a fan unit mounting structure according to a fifth embodiment of the present invention;

FIG. 11B is a side view showing the fan unit mounting structure according to the fifth embodiment of the present invention;

FIG. 12 is a plan view showing a fan unit mounting structure according to a sixth embodiment of the present invention;

FIG. 13A is a plan view showing a fan unit mounting structure according to a seventh embodiment of the present invention;

FIG. 13B is a plan view showing another fan unit mounting structure according to the seventh embodiment of the present invention;

FIG. 14A is an exploded perspective view of a conventional fan unit; and

FIG. 14B is a perspective view of the conventional fan unit having been assembled.

### BEST MODE FOR CARRYING OUT THE INVENTION

Before the description of the present invention proceeds, it is to be noted that like parts are designated by like reference numerals throughout the accompanying drawings.

Described below with reference to the drawings are some of the most preferred embodiments of the present invention.

### First Embodiment

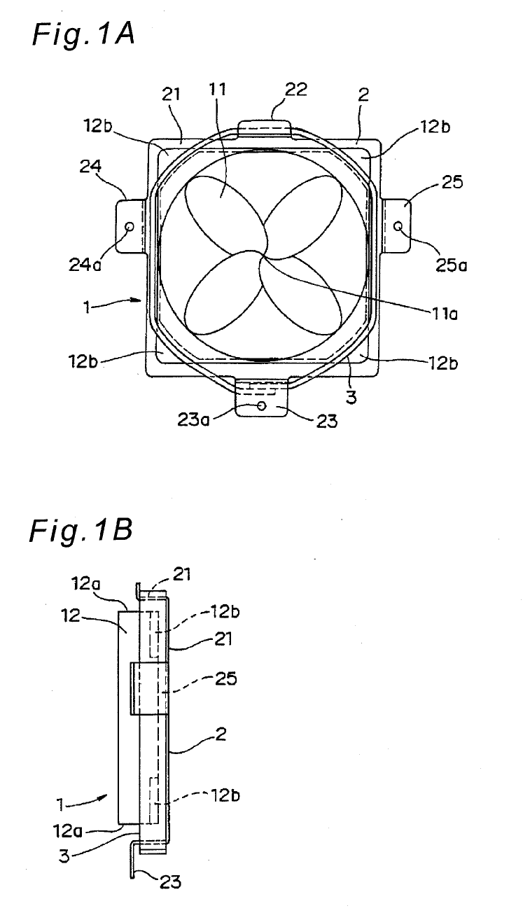

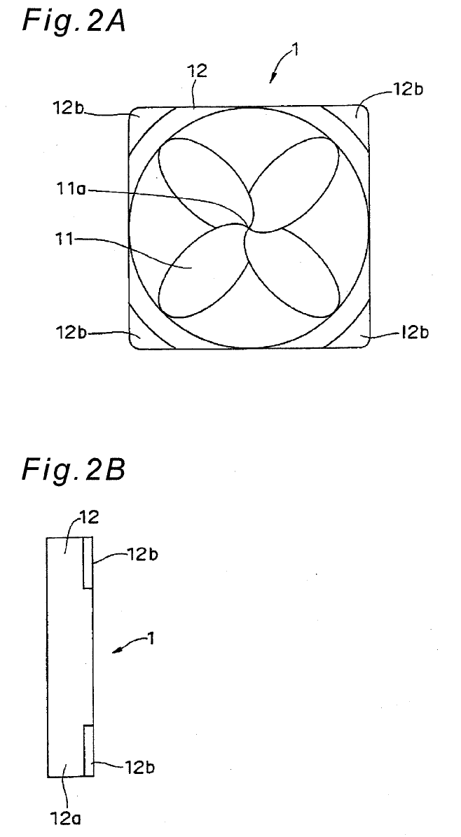

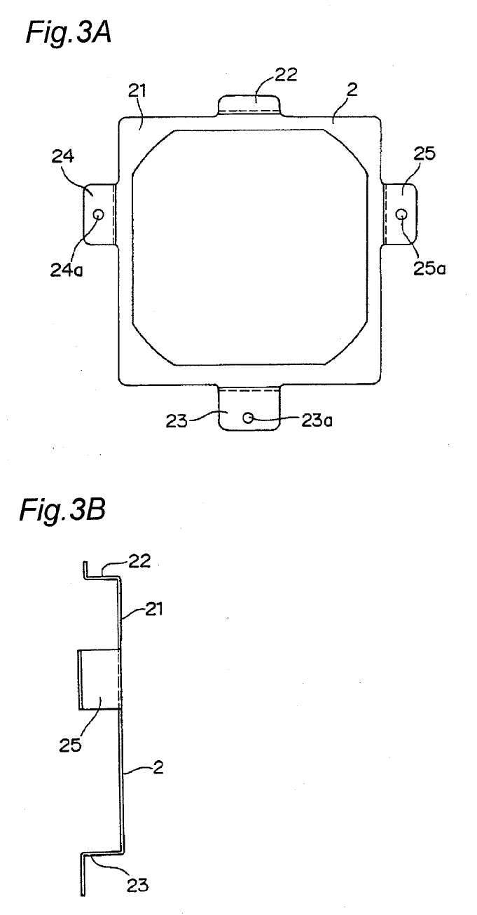

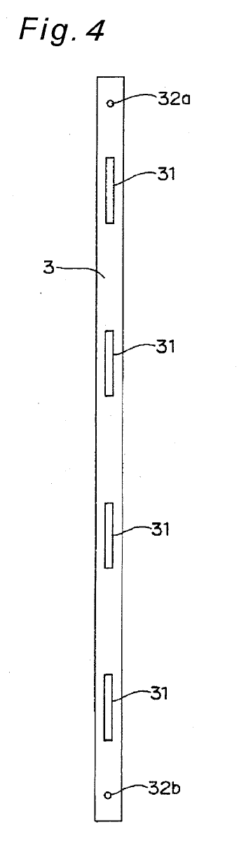

With reference to FIGS. 1A, 1B, 2A, 2B, 3A, 3B, and 4, there is described a fan unit mounting structure according to a first embodiment of the present invention. FIG. 1A is a plan view showing a state of a fan unit mounting frame and a belt-shaped elastic body respectively attached to a fan unit according to the first embodiment of the present invention, and FIG. 1B is a side view thereof. FIG. 2A is a plan view of the fan unit according to the first embodiment of the present invention, and FIG. 2B is a side view thereof. FIG. 3A is a plan view of the fan unit mounting frame according to the first embodiment of the present invention, and FIG. 3B is a side view thereof. FIG. 4 is a plan view of the belt-shaped elastic body according to the first embodiment of the present invention.

A fan unit 1 according to the first embodiment of the present invention is mounted to a fan unit mounting part in a casing of an electronic device. This fan unit is mounted particularly to an electronic device requiring suppression of drive noise (exemplified by a video device such as a liquid crystal display device, a plasma display device, a projection television device, or a personal computer).

According to the first embodiment of the present invention, the fan unit 1 is mounted to the fan unit mounting part with use of a fan unit mounting frame 2 and a belt-shaped elastic body 3. The fan unit mounting part is disposed on an inner surface of the casing of the electronic device or the electronic device body that includes a heat generating device and is located inside the casing, and this fan unit mounting part is used for mounting the fan unit 1.

In FIG. 2A, the fan unit 1 includes a fan 11 provided with a plurality of (FIG. 2A exemplifies a case with four) rotary blades, and a fan housing 12 that accommodates the fan 11 so as to be rotatable therein.

The fan 11 may function as a cooling fan for ventilating to cool the inside of the casing of the electronic device. There is mounted to the fan 11a drive motor (not shown), so that the fan 11 is driven by the drive motor so as to rotate about a rotary shaft 11a. The rotary shaft 11a of the fan 11 is coupled to the fan housing 12 by a coupling member (not shown).

The fan housing 12 is formed in substantially a cylindrical shape, and has an outer peripheral part 12a that is provided on a lower portion (the right portion in FIG. 2B) thereof with a plurality of (FIG. 2A exemplifies a case with four) flange parts 12b. As shown in FIG. 2A, the flange parts 12b each project radially from the outer peripheral part 12a so as to be distant from the rotary shaft 11a of the fan 11. The fan unit 1 has a substantially square outline due to the respective flange parts 12b when seen from a plane (that is, FIG. 2A) perpendicular to the rotary shaft 11a of the fan 11.

In FIGS. 3A and 3B, the fan unit mounting frame 2 has a frame body 21 in a rectangular-ring flat plate shape, a hanging hook part 22, a screwing/hanging hook part 23, and two screwing hook parts 24 and 25, that each project from one of sides on an outer peripheral part of the frame body 21 in a direction intersecting with (such as perpendicular to) a plane formed by the frame body 21 and each are bent outward at a distal end thereof.

The hanging hook part 22 and the screwing/hanging hook part 23 are disposed to face each other, while the two screwing hook parts 24 and 25 are disposed to face each other. The screwing/hanging hook part 23 has a vertically extended portion provided with a screw hole (not shown). The screwing/hanging hook part 23 and the two screwing hook parts 24, 25 have outwardly bent distal ends, which are provided with screwing holes 23a, 24a, and 25a, respectively. These screwing holes 23a, 24a, and 25a are provided correspondingly to three screw holes (not shown) that are formed in the fan unit mounting part, respectively. Alternatively, the fan unit mounting part may be provided with three screw holes correspondingly to the screwing holes 23a, 24a, and 25a. The fan unit mounting frame 2 is integrally fixed to the fan unit mounting part with use of screws that are inserted to the screw holes through the screwing holes 23a, 24a, and 25a, respectively.

In the present first embodiment, the hanging hook part 22 and the screwing/hanging hook part 23 each exemplify a fan unit mounting projection.

In FIG. 4, the belt-shaped elastic body 3 is a member made of an elastic body such as rubber into a belt shape. The belt-shaped elastic body 3 is provided with four slit holes 31 that exemplify a plurality of holes formed at constant intervals correspondingly to the positions and the sizes of the four flange parts 12b on the fan housing 12, and screwing holes 32a and 32b provided respectively in the vicinity of two ends thereof.

Described next with reference to FIGS. 1A and 1B is an exemplified process of mounting the fan unit 1 to the fan unit mounting frame 2.

Firstly, the screw hole (not shown) formed in the vertically extended portion of the screwing/hanging hook part 23 is aligned with the screwing hole 32a formed in the first end of the belt-shaped elastic body 3.

While this aligned state being maintained, the flange parts 12b of the fan unit 1 are gradually inserted to the slit holes 31 in the belt-shaped elastic body 3 respectively such that the outer peripheral part of the fan unit 1 is surrounded by the belt-shaped elastic body 3. As shown in FIGS. 1A and 1B, during this process, the center portion of the belt-shaped elastic body 3 is hung onto the hanging hook part 22.

Upon completion of insertion of the flange parts 12b respectively to the slit holes 31, the screwing hole 32b formed in the second end of the belt-shaped elastic body 3 is placed on the screw hole (not shown) and the screwing hole 32a already aligned with each other, and these three holes are aligned with one another. Thereafter, there is mounted a screw (not shown) so as to pass through these three holes.

In this way, the fan unit 1 is retained, while being spaced apart from the plane formed by the frame body 21 as shown in FIG. 1B, due to the clipping force of the belt-shaped elastic body 3. In a state where the frame body 21 is attached to the fan unit mounting part, the plane formed by the frame body 21 substantially corresponds to the fan unit mounting part. In other words, in the state where the frame body 21 is attached to the fan unit mounting part, the fan unit 1 is retained while being floated from the fan unit mounting part in the direction along the rotary shaft 11a of the fan 11 due to provision of the belt-shaped elastic body 3.

The fan unit 1 may be mounted to the fan unit mounting part after only the fan unit mounting frame 2 is attached to the fan unit mounting part, or after the fan unit 1 is mounted to the fan unit mounting frame 2 with use of the belt-shaped elastic body 3.

As described above, in a case where the driven fan 11 causes vibration in the direction perpendicular to the rotary shaft 11a of the fan 11 in the fan unit 1 retained by the belt-shaped elastic body 3, the belt-shaped elastic body 3 is bent in this perpendicular direction while clipping the fan unit 1 so as to absorb the vibration. Accordingly suppressed is transmission of the vibration to the fan unit mounting frame 2 that is integrally fixed to the fan unit mounting part, which results in suppression of noise.

Further, as described above, in a case where the driven fan 11 causes vibration in the direction along the rotary shaft of the fan 11 in the fan unit 1 retained by the belt-shaped elastic body 3, the belt-shaped elastic body 3 is bent in the direction along the rotary shaft while clipping the fan unit 1 so as to absorb the vibration in the direction along the rotary shaft of the fan 11. Therefore, it is possible to suppress transmission of the vibration to the fan unit mounting frame 2 that is integrally fixed to the fan unit mounting part. In this case, the fan unit 1 is retained while being floated from the fan unit mounting part in the direction along the rotary shaft of the fan 11. Accordingly, even in a case where the fan unit 1 is displaced in the direction along the rotary shaft due to the belt-shaped elastic body 3 that is bent in the direction along the rotary shaft of the fan 11, it is possible to inhibit contact between the fan unit 1 and the fan unit mounting part. As a result, the vibration caused by the driven fan 11 is inhibited from being transmitted to the fan unit mounting part so as to achieve suppression of noise.

Preferably, a plurality of contact portions between the belt-shaped elastic body 3 and the outer peripheral part 12a of the fan unit 1 (fit portions between the slit holes 31 and the flange parts 12b) are located so as to be distant respectively from contact portions between the belt-shaped elastic body 3 and the plurality of fan unit mounting projections (the hanging hook part 22 and the screwing/hanging hook part 23). More preferably, these contact portions are located so as to be evenly dispersed. In this configuration, the belt-shaped elastic body 3 is allowed to apply the elastic force (the clipping force) evenly to the fan unit 1 so as to maintain a constant space between the fan unit 1 and the fan unit mounting part.

In the first embodiment of the present invention, the fan unit 1 is made in contact only with the belt-shaped elastic body 3, so that the level of noise is dependent on the degree of hardness of the belt-shaped elastic body 3. A low degree of hardness set to the belt-shaped elastic body 3 increases the vibration absorption effect while reducing the force of retaining (clipping) the fan unit 1. To the contrary, a high degree of hardness set to the belt-shaped elastic body 3 increases the force of retaining (clipping) the fan unit 1 while reducing the vibration absorption effect. In the expression the other way around, the noise suppression effect can be further increased by balancing the size and weight as well as the vibration property with the impact resistance retention property in the fan unit 1 to appropriately select the degree of hardness of the belt-shaped elastic body 3.

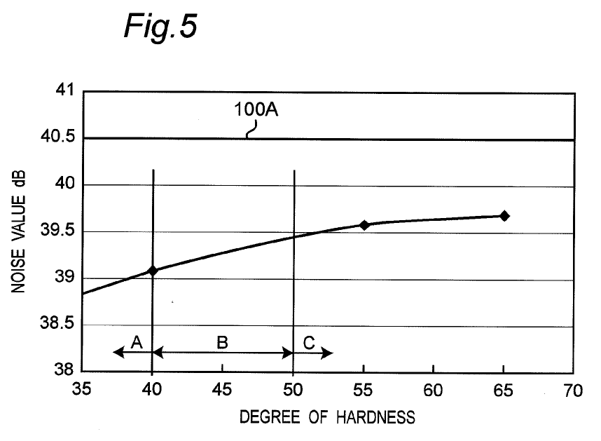

The above conditions are described below with reference to FIG. 5. FIG. 5 is a graph indicating a relation between degrees of hardness of the belt-shaped elastic body 3 and values of noise caused by the driven fan 11. The data on the degrees of hardness indicated in FIG. 5 is based on JIS K6301A. The conditions for measuring noise caused by the driven fan 11 are set as follows:

Fan: Fan Motor manufactured by NIDEC CORPORATION, Model Number D08A-12BL01B, 80 mm square with 25 mm thick

Fan Drive Voltage: 12 V

Measurement Position: a location distant by 1 m from the fan mounted in a casing (with no obstacle therebetween)

As shown in FIG. 5, the noise value is equal to 39.1 dB (decibel) with the belt-shaped elastic body 3 having the hardness of 40 degrees, while the noise value is equal to 39.6 dB (decibel) with the belt-shaped elastic body 3 having the hardness of 55 degrees, and the noise value is equal to 39.7 dB (decibel) with the belt-shaped elastic body 3 having the hardness of 65 degrees. To the contrary, the noise value was constantly equal to 40.5 dB when measured under similar conditions in a conventional fan unit mounting structure 100A for fixing a fan unit to a fan unit mounting part with use of a screw.

Found from the above results is that the fan unit mounting structure according to the present embodiment has the noise values smaller than that of the conventional fan unit mounting structure 100A in any of the cases where the belt-shaped elastic body 3 is set to have a hardness of a degree within the measurement range (35 to 70 degrees).

On the other hand, in some of cases where the belt-shaped elastic body 3 has a hardness of less than 40 degrees (corresponding to the area indicated by arrow A in FIG. 5), the belt-shaped elastic body 3 did not exert a force enough to retain (clip) the fan unit 1 and was incapable of retaining the fan unit 1. Further, in cases where the belt-shaped elastic body 3 has a hardness of more than 50 degrees (corresponding to the area indicated by arrow C in FIG. 5), the sensible noise was slightly large.

According to the above results, the belt-shaped elastic body 3 will be preferably set to have a hardness of 40 degrees or more, and will be more preferably set to have a hardness ranging from 40 to 50 degrees (corresponding to the area indicated by arrow B in FIG. 5).

Although not shown in the drawings, also in a case of using, in place of the fan described above, a cooling fan generally adopted in a commercial electrical device of 40 to 120 mm with the rotational speed of several hundreds to several thousands RPM, as well as using a belt-shaped elastic body 3 of 2 to 3 mm thick and 10 mm wide, it has been similarly confirmed that the belt-shaped elastic body 3 is preferably set to have a hardness of 40 degrees or more and is more preferably set to have a hardness ranging from 40 to 50 degrees.

As described above, in the structure used for mounting the fan unit 1 according to the first embodiment of the present invention, the fan unit 1 is retained, while being spaced apart from the casing in the direction along the rotary shaft of the fan 11, due to the clipping force of the belt-shaped elastic body. Accordingly, vibration caused by the driven fan is inhibited from being transmitted to the fan unit mounting part, resulting in suppression of noise.

The belt-shaped elastic body 3 is a component obviously larger in size in comparison to any of the elastic bodies adopted in Patent Documents 1 and 2, and therefore is hard to be deformed by a slight external force and is easily handled. In a case where the belt-shaped elastic body 3 is set to have a hardness of 40 degrees or more in order to provide a force of retaining the fan unit 1, the belt-shaped elastic body 3 is made harder to be deformed and is more easily handled. Accordingly facilitated is the mounting operation involving the belt-shaped elastic body 3, and the fan unit mounting operation can be easily performed.

Since the temperature rises (such as 50° C.) in a casing of an electronic device, the material for the belt-shaped elastic body 3 is preferably selected from substances such as a silicon rubber and a chloroprene rubber, which each have during the live thereof stable vibration absorption and strength properties with no deterioration even under a high temperature. It is confirmed by the accelerated environmental testing that the belt-shaped elastic body 3 made of one these substances has properties hardly deteriorated under a possible environment and for a possible duration of use (average ambient temperature 50° C., maximum temperature 80° C., and extension percentage 10%, for 24000 hours).

### Second Embodiment

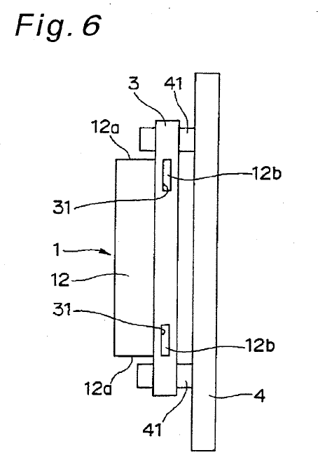

It is noted that the present invention is not limited to the embodiment described above but may be embodied in accordance with other various aspects. Shown in FIG. 6 is a fan unit mounting structure according to a second embodiment of the present invention. FIG. 6 is a side view showing the fan unit mounting structure according to the second embodiment of the present invention.

In the first embodiment described above, the fan unit mounting projections were exemplified respectively by the hanging hook part 22 and the screwing/hanging hook part 23 of the fan unit mounting frame 2. In the fan unit mounting structure according to the present second embodiment, in place of the above parts, there are provided a plurality of fan unit mounting projections 41 directly to a device body 4 that is disposed in a casing of an electronic device. As the details other than the above are similar to those of the first embodiment, description thereof will not be repeatedly provided.

In the fan unit mounting structure according to the present second embodiment, there are required no mount components such as a fan unit mounting frame 2 and a screw used for attaching the frame, thereby achieving further reduction in the number of components as well as cost reduction. In addition, further facilitated is the operation of mounting the fan unit 1.

### Third Embodiment

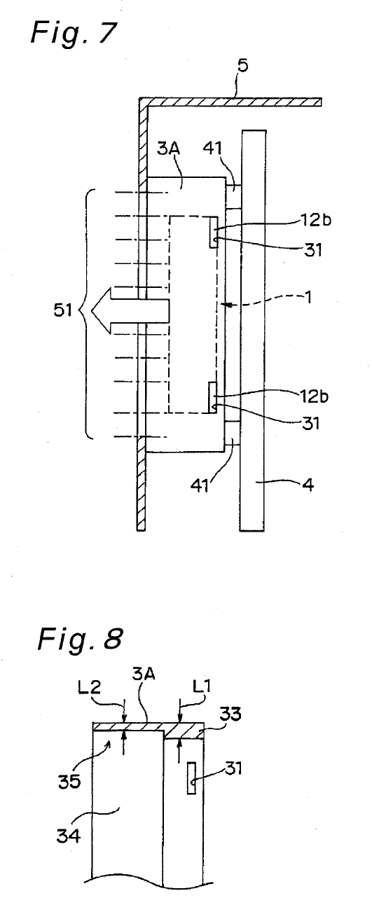

Described with reference to FIG. 7 is a fan unit mounting structure according to a third embodiment of the present invention. FIG. 7 is a side cross sectional view showing the fan unit mounting structure according to the third embodiment of the present invention.

A fan unit 1 and a casing 5, which configures an outline of an electronic device, are generally disposed with a predetermined space (such as several mm or more) provided therebetween in order to avoid transmission of vibration due to a driven fan 11 to the casing 5 and to result in noise. This space may not allow an airflow discharged from the fan unit 1 to be guided to discharge openings 51 (generally having an aperture ratio ranging from 30 to 60%) formed in the casing 5, thereby resulting in reduction in airflow and thus deterioration in cooling efficiency.

In order to improve these issues, in the fan unit mounting structure according to the third embodiment of the present invention as shown in FIG. 7, provided in place of the belt-shaped elastic body 3 (see FIG. 6) is a belt-shaped elastic body 3A that is formed to extend from the portion for retaining the fan unit 1 toward the discharge openings 51 (so as to be made in contact with the peripheral portion of the discharge openings 51, as an example). In other words, the third embodiment of the present invention adopts the belt-shaped elastic body 3A that is obtained by extending the portion close to the discharge openings 51 in the belt-shaped elastic body 3 toward the discharge openings 51. The belt-shaped elastic body 3A has two ends fixedly coupled with each other so as to form a ring shape, with a discharge wind tunnel part formed therein. This wind tunnel part guides the airflow discharged from the fan unit 1 to the discharge openings 51. As the details other than the above are similar to those of the second embodiment, description thereof will not be repeatedly provided.

In the fan unit mounting structure according to the third embodiment of the present invention, the belt-shaped elastic body 3A configures the discharge wind tunnel part so that the airflow discharged from the fan unit 1 is guided to the discharge openings 51, thereby suppressing deterioration in cooling efficiency.

In a case where the discharge wind tunnel part is made of a resin or a metal, vibration of the fan unit 1 may be transmitted by way of the portion for forming the wind tunnel part to generate noise.

To the contrary, in the fan unit mounting structure according to the third embodiment of the present invention, the wind tunnel part is configured by the belt-shaped elastic body 3A so as to absorb vibration of the fan unit 1 and to suppress generation of noise. Furthermore, retention of the fan unit 1 and provision of the wind tunnel part can be both achieved by the single belt-shaped elastic body 3A, resulting in significant reduction in the number of components in comparison to a conventional case. Therefore remarkably reduced is the number of assembling steps so as to facilitate the operation of mounting the fan unit 1.

As shown in FIG. 8, in order to suppress as much as possible transmission of vibration of the fan unit 1 to the casing 5, a wind tunnel part forming portion 35 for forming a wind tunnel part 34 is preferably set to have a thickness L2 smaller than a thickness L1 of a retentive portion 33 in the fan unit 1. More preferably, the thickness of the wind tunnel part forming portion 35 is half or less of the thickness of the retentive portion 33 (in a case where the thickness of the retentive portion 33 is equal to 3.0 mm, the wind tunnel part forming portion 35 is set to have the thickness of 1.5 mm or less).

The thickness of the retentive portion 33 can be easily differentiated from the thickness of the wind tunnel part forming portion 35 by manufacturing these portions by rubber extrusion molding or the like.

Although FIG. 8 shows that there is provided a step at a boundary between the retentive portion 33 and the wind tunnel part forming portion 35, the present invention is not limited to this case. Alternatively, the retentive portion 33 and the wind tunnel part forming portion 35 may be connected with each other so as to form a boundary in a gradually inclined straight line, that is, in a tapered shape.

### Fourth Embodiment

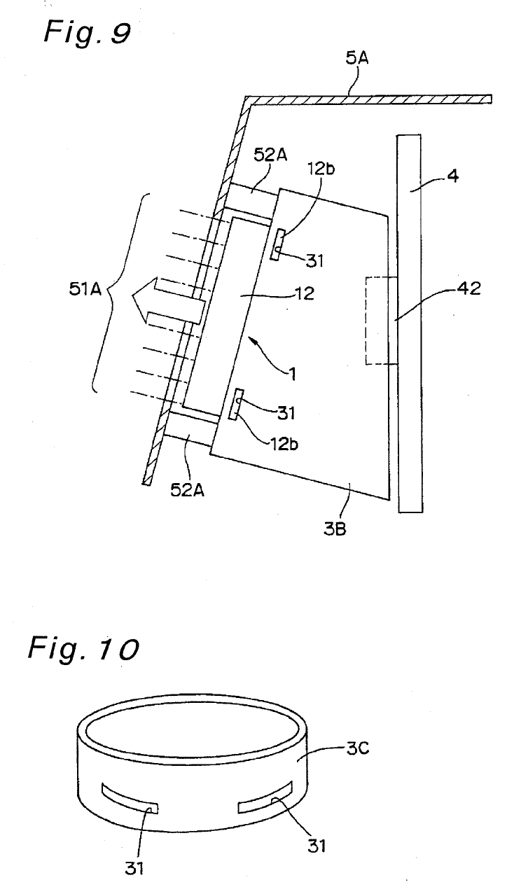

Described with reference to FIG. 9 is a fan unit mounting structure according to a fourth embodiment of the present invention. FIG. 9 is a side cross sectional view showing the fan unit mounting structure according to the fourth embodiment of the present invention.

In the fan unit mounting structure according to the fourth embodiment of the present invention as shown in FIG. 9, in place of the plurality of fan unit mounting projections 41 (see FIG. 7) provided to the device body 4, there are provided to a casing 5A a plurality of fan unit mounting projections 52A. In other words, the fan unit mounting part is provided on the casing 5A. In this case, the fan unit 1 may be made distant from a heat generating component 42 that is disposed to the device body 4, resulting in deterioration in cooling efficiency.

In order to prevent such a issue, in the fan unit mounting structure according to the fourth embodiment of the present invention as shown in FIG. 9, in place of the belt-shaped elastic body 3A (see FIG. 7), there is further provided a belt-shaped elastic body 3B that is formed to extend from the portion for retaining the fan unit 1 toward the heat generating component 42 disposed to the device body 4 (so as to cover the periphery of the heat generating component 42, as an example). The belt-shaped elastic body 3B has two ends fixedly coupled with each other so as to form a ring shape, with a suction wind tunnel part configured therein. This wind tunnel part guides air wormed by the heat generating component 42 to the fan unit 1. As the details other than the above are similar to those of the third embodiment, description thereof will not be repeatedly provided.

In the fan unit mounting structure according to the fourth embodiment of the present invention, the belt-shaped elastic body 3B configures the suction wind tunnel part so that air warmed by the heat generating component 42 is guided to the fan unit 1, thereby suppressing deterioration in cooling efficiency.

Further, in the fan unit mounting structure according to the fourth embodiment of the present invention, the wind tunnel part is configured by the belt-shaped elastic body 3B so as to absorb vibration of the fan unit 1 and to suppress generation of noise. Furthermore, retention of the fan unit 1 and provision of the wind tunnel part can be both achieved by the single belt-shaped elastic body 3B, resulting in significant reduction in the number of components in comparison to a conventional case. Therefore remarkably reduced is the number of assembling steps so as to facilitate the operation of mounting the fan unit 1.

In each of the embodiments described above, the ring-shaped elastic body is formed by fixedly coupling the two ends of the belt-shaped elastic body. However, the present invention is not limited to this case. Alternatively, as shown in FIG. 10, there may be configured a ring-shaped elastic body 3C that is originally formed in a ring shape (a rubber band shape).

The ring-shaped elastic body 3C may be attached as follows.

Firstly, the ring-shaped elastic body 3C is elongated to have a larger diameter by an external force.

Thereafter, the fan unit 1 is disposed inside the elongated ring-shaped elastic body 3C, and the plurality of flange parts 12b of the fan unit 1 are fitted in the slit holes 31, respectively. The ring-shaped elastic body 3C is thus attached to the outer peripheral part 12a of the fan unit 1.

Then, portions of the ring-shaped elastic body 3C located respectively between the adjacent slit holes 31 are clipped so as to be elongated, which are hung onto the fan unit mounting projections. As a result, the fan unit 1 can be retained by the ring-shaped elastic body 3C while being spaced apart from the fan unit mounting part.

In the case where the fan unit 1 is retained by the ring-shaped elastic body 3C, there is required none of the screwing holes 32a and 32b and screws to be fitted thereinto.

The ring-shaped elastic body 3C may be manufactured as follows.

There is firstly formed a cylindrical elastic body by rubber extrusion molding. The cylindrical elastic body is then double-layered by folding so as to bring the inner surface thereof into contact with each other. The double-layered elastic body is pressed to have slit holes 31 formed at constant intervals. Subsequently, this cylindrical elastic body is cut into an arbitrary width to obtain the ring-shaped elastic body 3C.

In this way, the ring-shaped elastic body 3C can be easily manufactured at a low cost.

### Fifth Embodiment

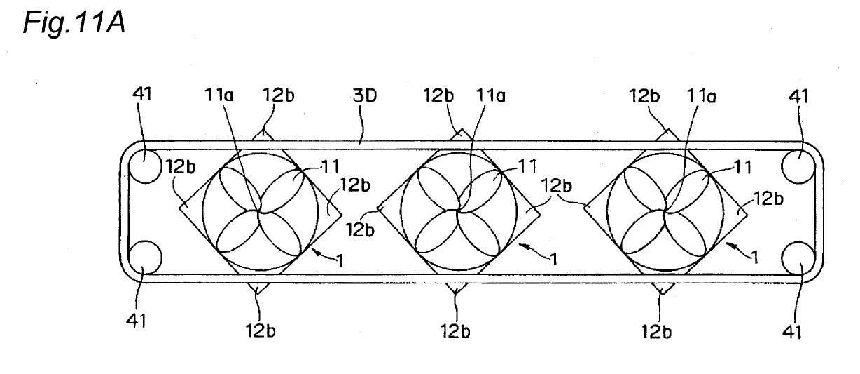

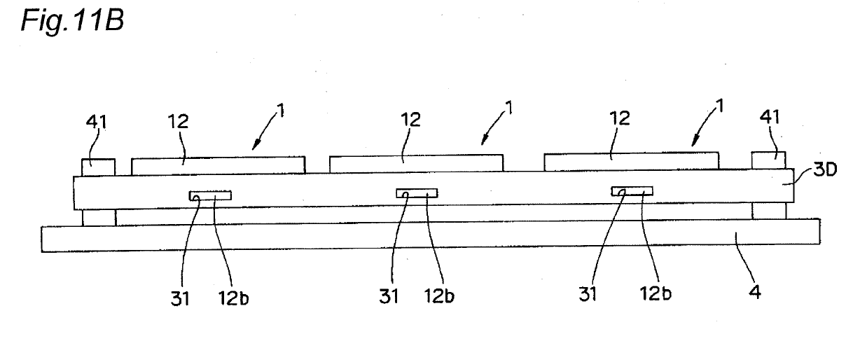

Described with reference to FIGS. 11A and 11B is a fan unit mounting structure according to a fifth embodiment of the present invention. FIG. 11A is a plan view showing the fan unit mounting structure according to the fifth embodiment of the present invention, and FIG. 11B is a side view thereof.

In the fan unit mounting structure according to the fifth embodiment of the present invention, a plurality of (three as an example) fan units 1 are disposed respectively between a plurality of (four as an example) fan unit mounting projections 41, and there is provided a belt-shaped elastic body 3D so as to inclusively surround these parts. As shown in FIG. 11B, the belt-shaped elastic body 3D is provided with a plurality (twice or more of the number of fan units 1) of slit holes 31. At least two diagonal flange parts 12b of each of the fan units 1 are inserted to the corresponding slit holes 31, and the belt-shaped elastic body 3D is hung onto the respective fan unit mounting projections 41 (or screwed thereto), so that the respective fan units 1 are retained by the belt-shaped elastic body 3D. More specifically, due to the clipping force of the belt-shaped elastic body 3D, the respective fan units 1 are retained while being spaced apart from the fan unit mounting part (located on the device body 4 in this case). As the details other than the above are similar to those of the second embodiment, description thereof will not be repeatedly provided.

In the fan unit mounting structure according to the fifth embodiment of the present invention, the plurality of fan units 1 are retained by the single belt-shaped elastic body 3D. Accordingly achieved are further reduction in the number of components as well as reduction in the number of assembling steps, which results in further facilitation in the operation of mounting the fan units 1.

### Sixth Embodiment

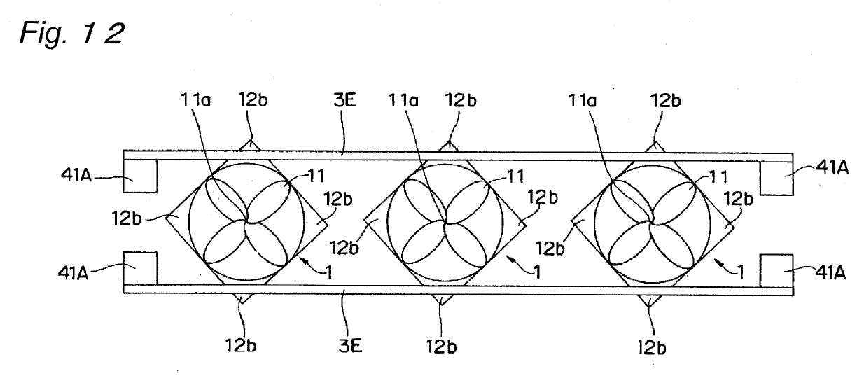

Described with reference to FIG. 12 is a fan unit mounting structure according to a sixth embodiment of the present invention. FIG. 12 is a plan view showing the fan unit mounting structure according to the sixth embodiment of the present invention.

In the fan unit mounting structure according to the sixth embodiment of the present invention as shown in FIG. 12, there are provided, in place of the belt-shaped elastic body 3D, two belt-shaped elastic bodies 3E and 3E that each have a length half or less of that of the belt-shaped elastic body 3D (see FIG. 11A). The belt-shaped elastic bodies 3E and 3E are each hung between a pair of separate fan unit mounting projections 41A. The belt-shaped elastic body 3E is fixed to the corresponding fan unit mounting projections 41A with use of bolts or the like. There are aligned a plurality of (three as an example) fan units 1 between the belt-shaped elastic bodies 3E and 3E that face each other. At least two diagonal flange parts 12b of each of the fan units 1 are inserted to a plurality of corresponding slit holes (not shown) formed in each of the belt-shaped elastic bodies 3E and 3E, so that the respective fan units 1 are retained by the belt-shaped elastic bodies 3E and 3E. More specifically, the respective fan units 1 are retained, while being spaced apart from the fan unit mounting part, due to the clipping forces of the respective belt-shaped elastic bodies 3E and 3E. As the details other than the above are similar to those of the fifth embodiment, description thereof will not be repeatedly provided.

In the fan unit mounting structure according to the sixth embodiment of the present invention, the plurality of fan units 1 are retained by the two belt-shaped elastic bodies 3E and 3E. More specifically, unlike the respective embodiments described above, each of the belt-shaped elastic bodies is configured to retain the fan units 1 with the two ends thereof not being fixedly coupled with each other. Even in such a configuration, the fan units 1 can be retained while being spaced apart from the fan unit mounting part.

Although the fan units 1 are retained by the two belt-shaped elastic bodies 3E and 3E in the above configuration, the present invention is not limited thereto. Alternatively, the fan units 1 may be retained by more than two belt-shaped elastic bodies.

### Seventh Embodiment

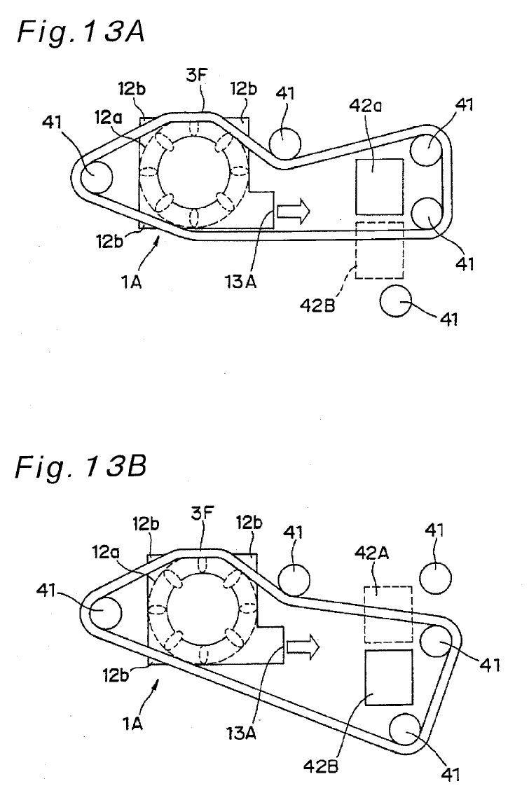

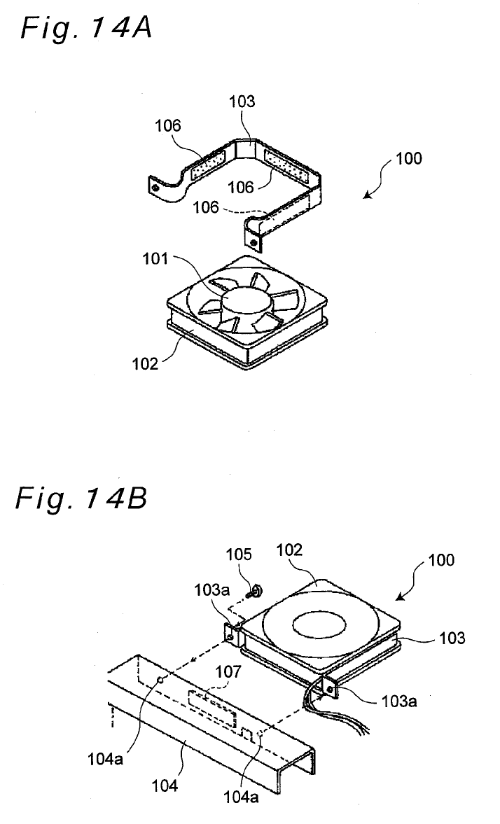

Described with reference to FIGS. 13A and 13B is a fan unit mounting structure according to a seventh embodiment of the present invention. FIGS. 13A and 13B are plan views each showing the fan unit mounting structure according to the seventh embodiment of the present invention.

Shown in each of FIGS. 13A and 13B is not a structure used for mounting the fan unit 1 of the axial flow type for blowing air in the direction along the rotary shaft 11a as described above, but a structure used for mounting a fan unit 1A of the sirocco type for suctioning air in the direction along the rotary shaft (in the direction perpendicular to the plane shown in FIG. 13A) and discharging an airflow from a blast opening 13A.

The fan unit 1A has an outer peripheral part 12a that is provided with a plurality of (three as an example) flange parts 12b similarly to the fan unit 1. The blast opening 13A is formed partially on the outer peripheral part 12a of the fan unit 1A.

The heat generating component 42 (see FIG. 9) disposed to the device body 4 may be located at a position slightly different from each other or may generate heat of which quantity is different from one another among the separate devices. Specifically, there is a case where the heat generating component 42 is located at a position 42A (see FIG. 13A), and there is another case where the heat generating component 42 is located at a position 42B (see FIG. 13B). In each of these cases, the heat generating component 42 may not be appropriately supplied with an airflow discharged from the blast opening 13A of the fan unit 1A, which will result in deterioration in cooling efficiency.

In order to inhibit such a issue, according to the seventh embodiment of the present invention, in the case where the heat generating component 42 (see FIG. 9) is located at the position 42A, as shown in FIG. 13A, a belt-shaped elastic body 3F is hung onto the plurality of fan unit mounting projections 41, and the respective flange parts 12b are fitted in a plurality of slit holes (not shown) that are provided in the belt-shaped elastic body 3F. The fan unit 1A is thus retained such that the blast opening 13A is directed to the position 42A. In this case, because the belt-shaped elastic body 3F is disposed so as to inclusively surround the fan unit 1A and the heat generating component 42, the belt-shaped elastic body 3F is allowed to guide an airflow from the blast opening 13A appropriately to the heat generating component 42, thereby resulting in increase in cooling efficiency.

On the other hand, in the case where the heat generating component 42 (see FIG. 9) is located at the position 42B, as shown in FIG. 13B, the belt-shaped elastic body 3F is hung onto the plurality of fan unit mounting projections 41, and the respective flange parts 12b are fitted in the plurality of slit holes (not shown) that are provided in the belt-shaped elastic body 3F. The fan unit 1A is thus retained such that the blast opening 13A is directed to the position 42B. In this case, because the belt-shaped elastic body 3F is disposed so as to inclusively surround the fan unit 1A and the heat generating component 42, the belt-shaped elastic body 3F is allowed to guide an airflow from the blast opening 13A appropriately to the heat generating component 42, thereby resulting in increase in cooling efficiency.

Therefore, in the fan unit mounting structure according to the seventh embodiment of the present invention, even in the case where the position of the heat generating component 42 or the quantity of heat generated by the heat generating component 42 is slightly different from one another among the separate devices, an airflow from the blast opening 13A can be appropriately guided to the heat generating component 42 by correspondingly selecting the positions to be hung onto the plurality of fan unit mounting projections 41. Moreover, it is possible to suppress deterioration in cooling efficiency only by selecting the positions to hang the belt-shaped elastic body 3F, which results in reduction in cost therefor.

In each of the embodiments described above, the belt-shaped elastic body is provided with slit holes 31 to which the flange parts 12b are respectively inserted, so that the belt-shaped elastic body retains the fan unit while being in contact with each other. However, the present invention is not limited to such a case. Alternatively, the fan unit may be retained only by the elastic force of the belt-shaped elastic body. Further alternatively, the belt-shaped elastic body and the fan unit may be fixed to each other with use of a screw. In such a case, the number of screwed locations is preferably reduced as much as possible (one location as an example), so that the belt-shaped elastic body is capable of absorbing vibration caused by the driven fan 1. Moreover, the fan unit mounting projections 22, 23, 41, and 52A are preferably provided to extend substantially in parallel with the outer peripheral part 12a of the fan unit 1 (1A) or with the rotary shaft 11a of the fan 11, so as to be made in contact with the outer peripheral part 12a of the fan unit 1 or 1A in a large area.

The respective effects can be exerted by appropriate combination of arbitrary embodiments in the various embodiments described above.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

The entire disclosure of Japanese Patent Application No. 2007-106840 filed on Apr. 16, 2007, including specification, claims, drawings, and summary are incorporated herein by reference in its entirety.

### INDUSTRIAL APPLICABILITY

A fan unit mounting structure according to the present invention inhibits transmission of vibration caused by a driven fan to a fan unit mounting part so as to achieve suppression of noise, as well as facilitates the operation of mounting the fan unit. The present invention is therefore useful in an electronic device requiring less drive noise, particularly in a video device such as a liquid crystal display device or a plasma display device.

1. A fan unit mounting structure used for mounting a fan unit to a fan unit mounting part in a casing of an electronic device, the structure comprising:
a plurality of fan unit mounting projections each extended substantially in parallel with a rotary shaft of a fan included in the fan unit and provided integrally to the fan unit mounting part; and
a belt-shaped elastic body hung onto each of the fan unit mounting projections,
the belt-shaped elastic body being made in contact with a plurality of locations on an outer peripheral part of the fan unit, and the fan unit being retained, while being spaced apart from the fan unit mounting part in a direction along the rotary shaft of the fan, due to a clipping force of the belt-shaped elastic body.

2. The fan unit mounting structure according to claim 1, wherein the fan unit mounting projections are provided to a fan unit mounting frame that is integrally fixed to the fan unit mounting part.

3. The fan unit mounting structure according to claim 2, wherein a plurality of contact portions between the belt-shaped elastic body and the outer peripheral part of the fan unit are located so as to be distant respectively from a plurality of contact portions between the belt-shaped elastic body and the respective fan unit mounting projections.

4. The fan unit mounting structure according to claim 3, wherein
the fan unit includes a plurality of flange parts on the outer peripheral part thereof,
the belt-shaped elastic body has a plurality of holes at positions respectively corresponding to the flange parts, and
the belt-shaped elastic body is hung onto each of the fan unit mounting projections, the flange parts of the fan unit are inserted respectively to the holes in the belt-shaped elastic body, and the fan unit is retained, while being spaced apart from the fan unit mounting part in the direction along the rotary shaft of the fan, due to the clipping force of the belt-shaped elastic body.

5. The fan unit mounting structure according to claim 3, wherein the belt-shaped elastic body has a hardness ranging from 40 to 50 degrees.

6. The fan unit mounting structure according to claim 3, wherein the belt-shaped elastic body is made of one of a silicon rubber and a chloroprene rubber.

7. The fan unit mounting structure according to claim 3, wherein
two ends of the belt-shaped elastic body are fixedly coupled with each other so as to form a ring-shaped elastic body, and
the ring-shaped elastic body is hung onto each of the fan unit mounting projections, the ring-shaped elastic body is made in contact with a plurality of locations on the outer peripheral part of the fan unit, and the fan unit is retained, while being spaced apart from the fan unit mounting part in the direction along the rotary shaft of the fan, due to the clipping force of the ring-shaped elastic body.

8. The fan unit mounting structure according to claim 7, wherein the ring-shaped elastic body is provided to extend from a portion for retaining the fan unit toward a discharge opening provided in the casing so as to form a discharge wind tunnel part.

9. The fan unit mounting structure according to claim 7, wherein the ring-shaped elastic body is provided to extend from a portion for retaining the fan unit toward a heat generating component disposed in the casing so as to form a suction wind tunnel part.

10. The fan unit mounting structure according to claim 8, wherein the ring-shaped elastic body has a portion for forming the wind tunnel part, a thickness of the portion being smaller than that of a portion for retaining the fan unit.

11. The fan unit mounting structure according to claim 7, wherein
the fan unit has a blast opening partially on the outer peripheral part, and
the ring-shaped elastic body is disposed to inclusively surround the fan unit and a heat generating component so that an airflow is guided from the blast opening toward the heat generating component disposed in the casing.
